(19) United States
(12) Patent Application Publication
(10) Pub. No.: US 2009/0167432 A1
(43) Pub. Date: Jul. 2, 2009

(54) INSTRUMENTATION AMPLIFICATION WITH INPUT OFFSET ADJUSTMENT

(76) Inventor: Nils van den HEUVEL, Amersfoort (NL)

Correspondence Address: Varian Inc.;Legal Department, 3120 Hansen Way D-102, Palo Alto, CA, 94304, US

(21) Appl. No.: 12/342,614

(22) Filed: Dec. 23, 2008

(30) Foreign Application Priority Data
Dec. 28, 2007 (EP) 07025219.2

(51) Int. Cl. H03F 3/45; H03F 1/36

(52) U.S. Cl. 330/69; 330/86

(57) ABSTRACT

In a single-ended or differential instrument amplifier, an input offset may be adjusted by driving current into the impedance of a feedback network of the amplifier. The amplifier may be provided with programmable gain capability. The impedance does not change with different gain settings, such that the input offset adjustment is equal for all gains. The amplifier may receive the output of a sensor such as, for example, a gas detector such as a thermal conductivity detector. The gas detector may be utilized to measure a gas flowing from a gas source such as, for example, a chromatographic column.

### FIELD OF THE INVENTION

This invention generally relates to electrical signal amplifiers and associated instrumentation. More particularly, the invention relates to signal amplifiers in which the adjustment of input offset is desirable. Such signal amplifiers may receive an output of a sensor, detector or transducer in an analytical or measuring instrument, with an undesired sensor offset being associated with the output.

### BACKGROUND OF THE INVENTION

Electronic instruments typically employ a sensor (or detector, transducer, etc.) to detect or measure a particular physical parameter or stimulus (e.g., sound, temperature, weight, force, pressure, thermal conductivity, etc.) and to convert the physical parameter to an electrical signal indicative of a value of the physical parameter. Sensors typically generate rather low electrical signals that are typically amplified in an input stage of the instrument. An input stage amplifier is typically characterized by a gain,

$$G = \frac{{V}_{out}}{{V}_{in}} ,$$

where Vₒᵤₜ>Vᵢₙ. Amplifiers are also typically powered by a DC power supply that provides both a positive and a negative bias, VDC and V−DC. Ideally, when a sensor does not detect a signal indicative of the physical parameter to be measured, the input signal Vᵢₙ is zero, and the output signal Vₒᵤₜ is also zero. When an input signal is sensed it is amplified to generate the output signal Vₒᵤₜ in both the positive and negative directions. There is a maximum level to the signal output Vₒᵤₜ. The DC positive and negative biases, VDC and V−DC, are the maximum signal levels (positive and negative) of the amplifier output Vₒᵤₜ.

One problem with many sensors is that they are not ideal and tend to generate some signal level in operation even without any stimulus from the physical parameter they are intended to measure. This is known as a sensor offset. In a thermal conductivity detector, the sensor offset may be caused by mismatches in the nominal resistances of the sensing elements (filaments, wires, etc.). A sensor offset at the input stage amplifier is amplified and produces a non-zero signal output, Vₒᵤₜ. The effect is to reduce the available output range of the amplifier. With a sensor output, the maximum input signal that may be detected is a signal level plus sensor offset that generates the signal output, Vₒᵤₜ=VDC or V−DC. Thus, to allow for large amplification and maintain the full output range of the amplifier, it is desirable to provide an input offset adjustment.

Amplifiers may advantageously be provided with a programmable gain. A programmable gain allows the user to select a gain that is optimal for the signal being generated by the sensor. A user may want to focus on a selected range of input signal levels. By selecting an appropriate gain, the user may obtain meaningful output signal levels through the entire output range of the amplifier. A programmable gain does not, however, account for the sensor offset. Once the desired gain is set, the user may still need to account for the sensor offset.

A thermal conductivity detector (TCD) is an example of a sensor commonly employed to measure changes in the thermal conductivity of a gas stream and thus is useful in a variety of applications such as, for example, gas chromatography (GC). A TCD may include a four-element bridge circuit, often arranged as a Wheatstone bridge, in which the elements are temperature-sensitive (thermal-sensing) elements such as resistive filaments or semiconducting thermistors (generally, resistors). The resistances of the sensing elements vary in response to temperature changes. The temperature of each sensing element in turn depends on the thermal conductivity of the gas flowing around the sensing element. At least one resistor (or one pair of resistors) may serve as a sample resistor, and at least one resistor (or one pair of resistors) may serve as a reference resistor. In a GC application, a reference voltage is sensed at both the sample and reference resistors in the presence of the carrier (reference) gas (e.g., hydrogen, helium, etc.), and a sample voltage is sensed at the sample resistor(s) in the presence of the GC column effluent containing both the carrier gas and analyte molecules (peaks). As the sample gas is introduced, a temperature change is sensed by the sample resistors and the resulting change in resistance causes a change in the signal level at the sample resistors. This change in the signal level may be correlated to the temperature change and further with the concentration of the sample gas. The TCD may be arranged such that the effect of thermal conductivity of the carrier gas is canceled, and may be structured such that other effects such as variations in flow rate, pressure and electrical power are minimized.

TCDs are also subject to sensor offset. One source of sensor offset in a TCD may be caused by mismatches in the nominal resistances of the sensing elements (filaments, wires, etc.). Known technology has not adequately addressed this type of sensor offset.

In view of the foregoing, there is a need for systems, devices, circuits and methods that provide signal amplification and input offset adjustment, including in amplifiers capable of programmable gain.

### SUMMARY OF THE INVENTION

To address the foregoing problems, in whole or in part, and/or other problems that may have been observed by persons skilled in the art, the present disclosure provides apparatus, devices, systems and/or methods relating to amplifiers with input offset adjustment, as described by way of example in implementations set forth below.

According to one implementation, an amplifier circuit includes an amplifier including a non-inverting input, an inverting input, and an amplifier output, a feedback network in signal communication with the amplifier output and the inverting input, and a current source in signal communication with the inverting input. The current source is adjustable to a plurality of selectable input offsets to generate a plurality of corresponding voltage offsets at the inverting input.

According to another implementation, the feedback network is adjustable to a plurality of gain settings of the amplifier circuit. The feedback network is configured such that the impedance at the inverting input is equal for all gain settings, whereby the plurality of selectable input offsets and the plurality of corresponding voltage offsets are independent of the plurality of gain settings.

According to another implementation, an amplifier circuit includes a first amplifier, a second amplifier, a feedback network, and a current source. The first amplifier includes a first non-inverting input, a first inverting input, and a first amplifier output. The second amplifier includes a second non-inverting input, a second inverting input, and a second amplifier output. The feedback network is in signal communication with the first amplifier output, the first inverting input, the second amplifier output, and the second inverting input. The current source is in signal communication with the inverting input. The current source is adjustable to a plurality of selectable input offsets to generate a plurality of corresponding voltage offsets at the inverting input.

According to another implementation, the feedback network is adjustable to a plurality of gain settings of the amplifier circuit. The feedback network is configured such that the impedance between the first and second inverting inputs is equal for all gain settings, whereby the plurality of selectable input offsets and the plurality of corresponding voltage offsets are independent of the plurality of gain settings.

According to another implementation, the current source includes a first current source in signal communication with the first inverting input, and a second current source in signal communication with the first inverting input and with the second inverting input. At least one of the first and second current sources is adjustable to the plurality of selectable input offsets to generate a plurality of corresponding voltage offsets at the first and second inverting inputs.

According to another implementation, an amplifier circuit further includes a device or circuitry for adjusting the feedback network to a plurality of gain settings of the amplifier circuit. The impedance at the inverting input is equal for all gain settings, whereby the plurality of selectable input offsets and the plurality of corresponding voltage offsets are independent of the plurality of gain settings.

According to another implementation, an amplifier circuit includes an amplifier including a non-inverting input, an inverting input, and an amplifier output, a feedback network in signal communication with the output and the inverting input, and a device or circuitry for driving an adjustable current into the inverting input. The adjustable current is adjustable to a plurality of selectable input offsets to generate a plurality of corresponding voltage offsets at the inverting input.

According to another implementation, in any of the foregoing amplifier circuits, at least one amplifier may be in signal communication with a gas detector. In some implementations, the gas detector may be in flow communication with a chromatographic column. In some implementations, the gas detector may be a thermal conductivity detector (TCD).

According to another implementation, in any of the foregoing amplifier circuits, at least one amplifier may be in signal communication with a bridge output of a bridge circuit. The bridge circuit may include at least two temperature-sensitive resistive elements, one of the resistive elements communicating with a first gas source and the other resistive element communicating with a second gas source.

According to another implementation, a method for adjusting an input offset at an input of an amplifier circuit is provided. An input signal is amplified in a differential amplifier to generate an output signal. The output signal is fed back to an inverting input of the differential amplifier through a feedback network. An adjustable current is driven into the inverting input. The adjustable current is adjustable to a plurality of selectable input offsets to generate a plurality of corresponding voltage offsets at the inverting input.

According to another implementation, the method further includes adjusting the feedback network to a selected one of a plurality of selectable gain settings of the amplifier circuit, wherein the impedance at the inverting input is equal for any gain setting selected, whereby adjustment of the current is independent of the selected gain setting.

According to another implementation, the method further includes receiving an input signal at a non-inverting input of the differential amplifier from a gas detector. In some implementations, the input signal may be indicative of a concentration of a gas flowed from a chromatographic column. In some implementations, the gas detector may be a thermal conductivity detector

Other devices, apparatus, systems, methods, features and/or advantages of the invention will be or will become apparent to one with skill in the art upon examination of the following figures and detailed description. It is intended that all such additional devices, apparatus, devices, systems, methods, features and/or advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a schematic view of an example of an analytical instrument or system in which implementations of the invention may be practiced.

FIG. 2 is a schematic view of an example of a detector and amplifier with which implementations of the invention may be practiced.

FIG. 3 is a schematic view of an example of a single-ended instrumentation amplifier circuit with input offset adjustment according to one implementation.

FIG. 4 is a schematic view of an example of a differential instrumentation amplifier circuit with input offset adjustment according to another implementation.

FIG. 5 is a schematic view of another example of a single-ended instrumentation amplifier circuit with input offset adjustment according to another implementation.

FIG. 6 is a schematic view of another example of a differential instrumentation amplifier circuit with input offset adjustment according to another implementation.

FIG. 7 is a schematic view of another example of a single-ended instrumentation amplifier circuit with input offset adjustment according to another implementation.

FIG. 8 is a schematic view of another example of a differential instrumentation amplifier circuit with input offset adjustment consistent with the present invention.

### DETAILED DESCRIPTION OF THE INVENTION

In general, the term “communicate” (for example, a first component “communicates with” or “is in communication with” a second component) is used herein to indicate a structural, functional, mechanical, electrical, optical, magnetic, ionic or fluidic relationship between two or more components or elements. As such, the fact that one component is said to communicate with a second component is not intended to exclude the possibility that additional components may be present between, and/or operatively associated or engaged with, the first and second components.

In general, the phrase “in signal communication” refers to any means for passing and/or communicating a signal or information from a first device or component to a second device or component or to more than one other device or component. Examples of such means include, but are not limited to, connecting, electromagnetically coupling, transmitting and receiving wired or wirelessly, and passing after processing, filtering, converting, or modifying a signal or information.

In general, unless otherwise indicated or evident from the context, the term “impedance” or “impedance element” may refer to a resistance (or resistive) element such as a resistor, a capacitance (or capacitive) element such as a capacitor, an inductance (or inductive) element such as an inductor, combinations of more than one of the foregoing elements, combinations of one or more types of the foregoing elements, or devices or circuit portions exhibiting impedance. As appreciated by persons skilled in the art, resistors, capacitors, inductors, amplifiers, and the like may constitute one or more discrete components or portions of solid-state or integrated circuits (ICs).

The description below refers to thermal conductivity detectors (TCDs) as may be employed in gas chromatography as an example of a sensor that may be placed in signal communication with an input stage amplifier. By way of example, the TCD or other sensor may be employed in an instrument such as a gas chromatographic (GC) system. Despite the foregoing, persons skilled in the art will appreciate that examples consistent with the present invention may be utilized with any suitable sensor in any suitable application (weigh scales, pressure measurement, etc.). In addition, such sensors, including TCDs, may be powered by either direct current (DC) or alternating current (AC). In addition, implementations of the invention may be provided in discrete component form, in ICs, or in combination.

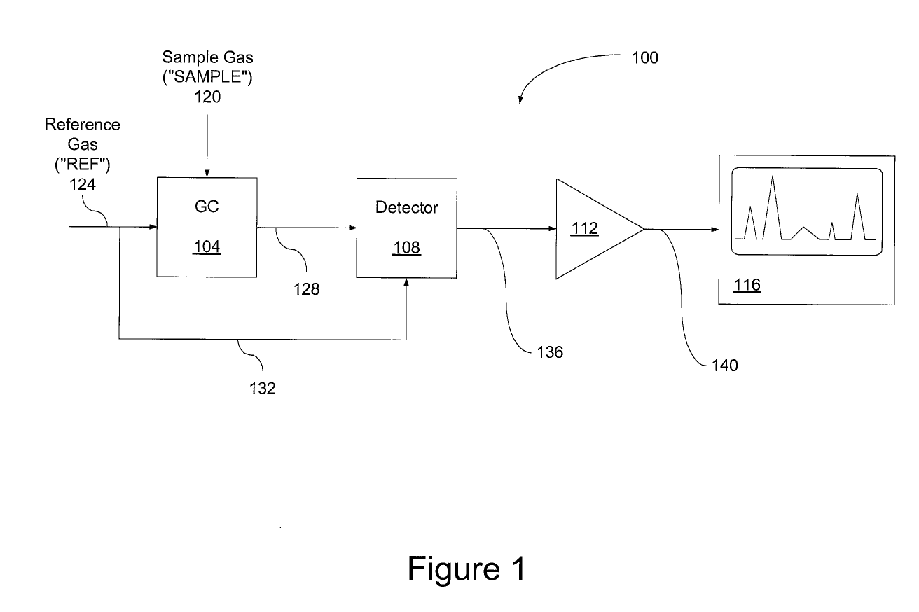

FIG. 1 is a schematic diagram of an example of an operating environment or system in which implementations of the invention may be practiced. FIG. 1 illustrates a gas chromatograph (GC) system 100 that may include a GC apparatus 104, a detector 108, a detector amplifier 112, and a readout/display device 116. Any type of GC apparatus 104 may be provided, the basic design and operating principles of which are known and need not be described in detail here. More generally, any apparatus providing a flow of gas to be analyzed may be provided, the illustrated GC apparatus 104 being but one example.

The detector 108 may be any suitable detector such as a thermal conductivity detector (TCD). An input 120 of sample gas and an input 124 of reference (carrier) gas are provided to the GC apparatus 104. An injector (not shown) is typically employed to combine the sample gas and the carrier gas such that the carrier gas carries the components of the sample gas through a chromatographic column (not shown) of the GC apparatus 104. The GC apparatus 104 may include an oven in which the column is located to heat the solute-carrier gas mixture flowing through the column, or alternatively (or additionally) may include a device or means for directly heating the column. The effluent (SAMPLE+REF) 128 from the GC column may be input into the detector 108. Additionally, at some point ahead of the sample injector of the GC apparatus 104, a portion 132 of the carrier (REF) gas flow may be diverted or split from the main carrier gas input 124 and directed separately to the detector 108. The detector 108 produces an output (measurement) signal 136 indicative of the concentration of the sample gas as the peaks are eluted from the column, such as may be correlated from measured thermal conductivity in the case of a TCD. The detector amplifier 112 amplifies the measurement signal 136 and outputs an amplified signal 140. The amplified signal 140 may be transmitted to additional signal conditioning and processing circuitry (not shown) as needed. The readout/display device 116 may be utilized to receive the amplified signal 140 and produce a chromatogram of peaks constituting user-interpretable results of the operation of the GC apparatus 104, for example TCD output response as a function of time.

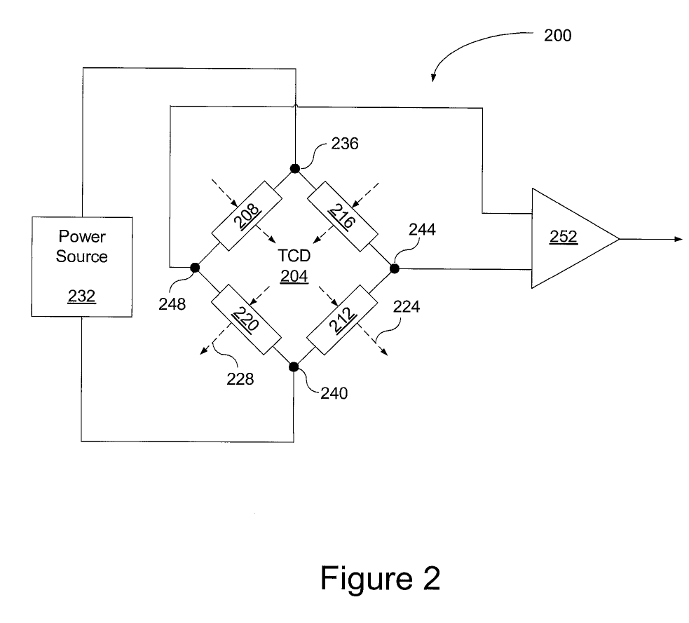

FIG. 2 is a schematic diagram of an example of a detector or detector circuitry 200 such as may be utilized in an analytical instrument system such as the GC system 100 illustrated in FIG. 1. The illustrated example is useful, for example, when the detector 200 is configured as a TCD. Accordingly, the detector 200 may include a sensor portion 204 arranged as a four-element bridge circuit housed in a suitable detector cell structure (not shown) in flow communication with a suitable gas source such as a GC apparatus. The legs or arms of the bridge circuit include an opposing pair of sample resistors 208 and 212 and an opposing pair of reference resistors 216 and 220. One (or both) of the sample resistors 208 and 212 are exposed to a mixed flow 224 of sample and carrier gas, for example, the effluent from a GC column. One (or both) of the reference resistors 216 and 220 are exposed to a flow 228 of reference gas only, which is separate from the carrier-sample effluent flow 224. As an example, the carrier gas employed for GC (e.g., helium, hydrogen, etc.) may serve as the reference gas. A power source 232 supplies an excitation voltage to input nodes 236 and 240 of the bridge circuit. One or both output nodes 244 and 248 may be connected in signal communication with a suitable instrument amplifier (IA) 252.

In a typical operation, when each gas flow 224 and 228 contains only reference gas (e.g., before sample peaks are eluted from a GC column), the respective temperatures of the four resistors 208, 212, 216, 220 of the bridge circuit should be the same and at a known value for the reference gas. The bridge circuit should be balanced and produce an output at some zero-level or baseline level indicative of the absence of sample gas. The thermal conductivity of a gas stream is dependent on the chemical composition of the gas. In most cases, the thermal conductivities of sample gas components are appreciably lower than the thermal conductivity of the reference gas. Hence, when the gas flow 224 includes sample components, the resulting thermal conductivity of the mixed flow 224 is lower than the thermal conductivity of the reference-only flow 228. Moreover, in the case of GC operation, the thermal conductivity of the mixed flow 224 changes relative to the thermal conductivity of the reference-only flow 228 as different peaks elute from the column. Consequently, the temperature(s) of the resistor(s) 208 and/or 224 in thermal contact with the mixed flow 224 change and likewise their resistance value(s) change, while the temperature(s) and resistance(s) of the resistor(s) 216 and/or 220 in thermal contact with the reference-only flow 228 remain constant. For example, the power source 232 and/or a separate heating device may be operated to initially heat the resistors 208, 212, 216, 220 to an equilibrium temperature, determined by the flow rate and thermal conductivity of the reference gas and the current through the resistors 208, 212, 216, 220, after which time heat is carried away from the resistors 208, 212, 216, 220 by the flowing gases. Thus, the presence of sample components in the mixed flow 224 causes an imbalance in the bridge circuit, which typically represents the difference in thermal conductivity between the sample gas and the reference gas. This difference is reflected in the output level of the bridge circuit as a measurement signal, which is then amplified by the instrument amplifier 252.

It will be noted that there are several ways to configure and power the bridge circuit illustrated in FIG. 2, including the following four examples. First, in a constant voltage method, a constant voltage may be applied across the bridge circuit. Second, in a constant current method, a constant current may be applied to the bridge circuit. In either of these two cases, the output signal of the bridge circuit is a function of the voltage imbalance appearing at the midpoint of the bridge circuit. Third, in a constant-temperature method, the output signal of the bridge circuit is utilized as a feedback voltage control to maintain the bridge circuit in a balanced state. In this case, the heat required to keep the temperature of the bridge elements constant is measured, instead of measuring the increase in temperature resulting from sample components. Fourth, in a constant mean temperature method, the bridge circuit is connected within a second bridge circuit and feedback control, in which case the output signal is the voltage imbalance across the inner bridge. Implementations of the present invention may be configured to operate with all such types of the bridge circuits.

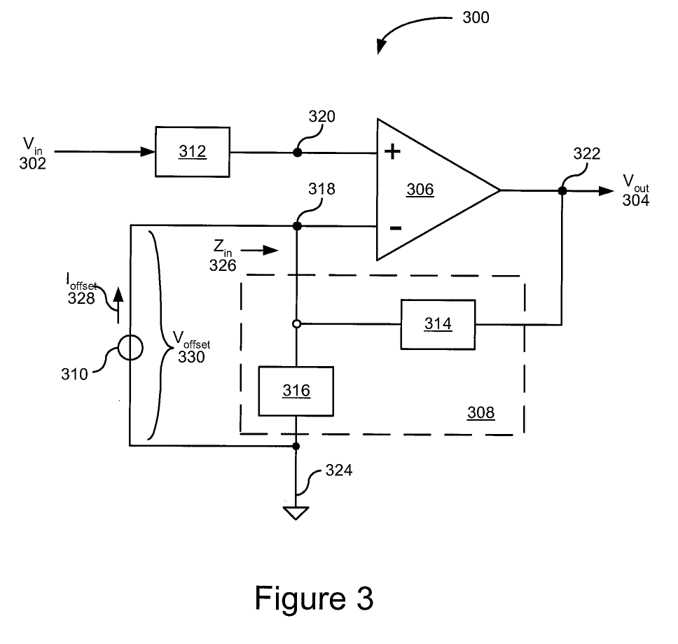

FIG. 3 is a schematic diagram of an example of an amplifier circuit 300 consistent with the present invention. The amplifier circuit 300 receives an input signal 302 and produces a corresponding output signal 304. The amplifier circuit 300 may include an amplifier element (generally referred to simply as an “amplifier”) 306, a feedback network 308, a current source 310, and a compensating impedance element 312. The feedback network 308 may include a first feedback impedance element 314 and a second feedback impedance element 316. In this example, the amplifier circuit 300 in FIG. 3 is a single-ended (current) signal instrumentation amplifier. A sensor (not shown), such as a bridge circuit operating as a TCD, may be in signal communication with the amplifier circuit 300 so as to provide the input signal 302. In one example, the input signal 302 may be indicative of changes in thermal conductivity of a sample gas being measured. For convenience, the ensuing description will refer to schematically illustrated impedance elements simply as “impedances.”

In the example illustrated in FIG. 3, the amplifier 306 in the amplifier circuit 300 is a differential amplifier having differential inputs, i.e., an inverting input 318 and a non-inverting input 320. As such, the amplifier 306 may be considered as having a “programmable gain” in that it may be programmed by selecting a suitable impedance value for the second feedback impedance 316. As an example, the amplifier 306 may be an operational amplifier generally known as an “op-amp.”

Utilizing an op-amp for the amplifier 306, the amplifier circuit 300 is in an inverting configuration where compensating impedance 312 is in signal communication with the non-inverting input 320 of the amplifier 306 and the feedback network 308 is in signal communication with both the output 322 of the amplifier 306 and the inverting input 318 of the amplifier 306. The current source 310 is also in signal communication with the inverting input 318 of the amplifier 306. In this example, the first impedance 314 is in signal communication with both the output 322 of the amplifier 306 and the inverting input 318 of the amplifier 306, and the second impedance 316 is in signal communication with the inverting input 318 of the amplifier 306 and a signal ground 324.

In this example, the current source 310 is in signal communication with the negative input node 318 to inject current into the input impedance Zᵢₙ 326 of the feedback network 308 formed by the first and second feedback impedances 314 and 316. The current injected by the current source 310 is a constant offset current, I_{offset} 328, which forms an offset voltage, V_{offset} 330, at the negative input node 318. In the example shown, the first feedback impedance 314 may be set to a resistive value of (g−1)*R where “g” is the gain of the amplifier 306, and the second feedback impedance 316 may be set to a resistive value of R where R is a resistance selected to program the gain of the amplifier 306. With these values for the first and second feedback impedances 314 and 316, the offset voltage V_{offset} 330 is:

V_{offset}=(R∥(g−1)R)I_{offset}, which can be restated as:

$${V}_{offset} = \frac{( g - 1 ) R}{g} {I}_{offset} .$$

The compensating impedance 312 may be inserted in series with the non-inverting input 320 of the amplifier element 340. The value of the compensating impedance 312 may be, in general, the value of the impedance of the parallel combination of the first and second feedback impedances 314 and 316 (i.e., the input impedance Zᵢₙ 326). That is, the value of the compensating impedance 312 in the example described above may be equal to

$$\frac{( g - 1 ) R}{g} .$$

The amplifier circuit 300 illustrated in FIG. 3 provides a user with the ability to control the current source 310 to inject a desired offset current, I_{offset} 328, to create a V_{offset} 330 that offsets the sensor offset contribution to the input signal 302. The current source 310 simplifies the process of sensor offset compensation by providing the user with just one parameter to adjust: I_{offset}. In one example of using the amplifier circuit 300, the user may set up a sensor to generate a ‘zero’ signal. The input offset adjustment may be controlled by the single-ended current input. A differential input or ground reference is not required. Thus, in setting the input offset adjustment, the user may configure a sensor to generate a signal that is selected to represent a zero level. In the case of a TCD employed with a GC, the sensor may be configured to provide a balanced signal level at the sensor output leads. That is, the sensor may be subjected to a temperature at which all of the resistor filaments should be of equal value. The user may then adjust the current source 310 to generate an I_{offset} offset 328 that applies a V_{offset} 330 at the inverting input 318 of the amplifier 306, and which generates an output signal 304 having a signal value representative of a zero level of sample gas.

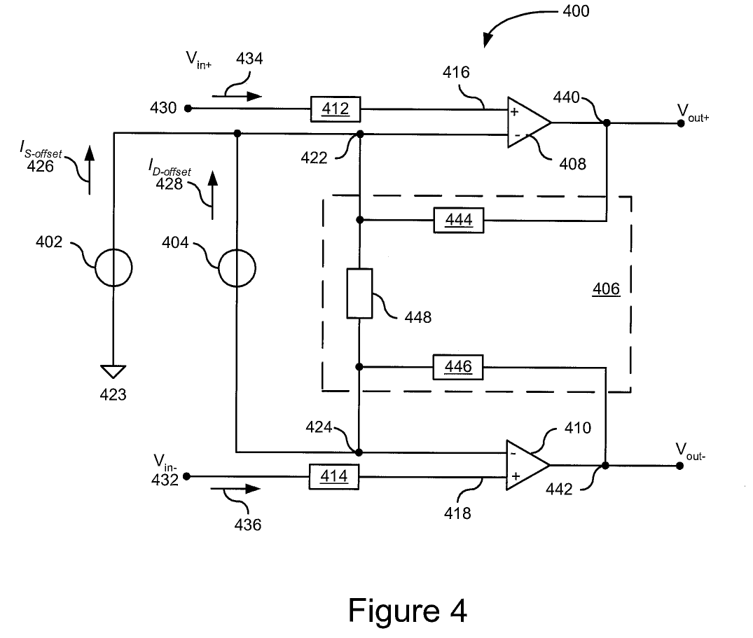

FIG. 4 is a schematic diagram of an example of a differential instrumentation amplifier circuit 400 consistent with the present invention. The amplifier circuit 400 may include first and second current sources 402 and 404, a feedback network 406, a first amplifier 408, a second amplifier 410, a first compensating impedance 412, and a second compensating impedance 414. In this example, the first amplifier 408 and second amplifier 410 are differential amplifiers such as, for example, op-amps. The first compensating impedance 412 is in signal communication with a non-inverting input 416 of the first amplifier 408 and the second compensating impedance 414 is in signal communication with a non-inverting input 418 of the second amplifier 410. The first current source 402 is in signal communication with an inverting input 422 of the first amplifier 408 and the second current source 404 is signal communication with both the inverting input 422 of the first amplifier 408 and an inverting input 424 of the second amplifier 410. The first current source 402 is also in signal communication with a signal ground 423. In operation, the first and second current sources 402 and 404 inject respective currents I_{S-offset} 426 and I_{D-offSet} 428 directly into a first negative input node, which corresponds to the inverting input 422 of the first amplifier 408.

A sensor such as the TCD in the bridge circuit described above may be connected with one lead from the bridge circuit to be in signal communication with a positive signal input 430 of the amplifier circuit 400 and the other lead connected in signal communication with a negative signal input 432 of the amplifier circuit 400. In this example, a positive input signal 434 injected into the positive signal input 430 passes through the first compensating impedance 412 to the non-inverting input 416 of the first amplifier 408. Similarly, a negative input signal 436 injected into the negative signal input 432 passes through the second compensating impedance 414 into the non-inverting input 418 of the second amplifier 410. The amplifier circuit 400 includes a positive differential output 440 corresponding to the output of the first amplifier 408 and a negative differential output 442 corresponding to the output of the second amplifier 410. The feedback network 406 is in signal communication with both the outputs 440 and 442 of the first and second amplifiers 408 and 410 and both the inverting inputs 422 and 424 of the first and second amplifiers 408 and 410. The feedback network 406 may include a first feedback impedance 444, second feedback impedance 446, and a gain impedance 448.

The amplifier circuit 400 may be considered as having “programmable gain” capabilities implemented by selecting a suitable impedance value for a selected gain impedance 448. In general, the operating characteristics of the first and second amplifiers 408 and 410 may be balanced. Accordingly, the first and second amplifiers 408 and 410 may have substantially the same specifications, the first and second feedback impedances 444 and 446 may be of the same impedance value, and the first and second compensating impedances 412 and 414 may be set to the same compensating impedance value. The gain impedance 448 provides the “programmable gain” capabilities in that the value of the gain impedance 448 may be varied or selected to achieve a desired gain for the amplifier circuit 400.

In this example, the values of the first feedback impedance 444, the second feedback impedance 446, and the gain impedance 448 may depend on achieving a desired range of offset voltages at the negative input nodes that correspond to the inverting inputs 422 and 424 of the first and second amplifiers 406 and 410, respectively. The desired range of offset voltages may depend on the range of sensor offsets expected from a selected sensor and on the current level of the input offset current. In this example, the impedance values may be selected as follows: the first and second feedback impedances 444 and 446 may be each set to an impedance value of (g−1)*R where “g” is the gain of each amplifier 408 and 410, and the gain impedance 448 may be correspondingly set to 2R, where “R” is a resistance value (i.e., a “real” impedance value) that a user may set depending on specific implementations according to a desired total gain. With these values for the first and second feedback impedances 444 and 446, and for the gain impedance 408, the offset voltage V_{offset} may be adjusted using the following relationship:

$${V}_{offset} = \frac{( g - 1 ) R}{g} {I}_{S \text{-} offset} + \frac{2 R ( g - 1 )}{g} {I}_{D \text{-} offset} .$$

Once a user has achieved a desired gain from the amplifier circuit 400, the voltage offset V_{offset} may be adjusted to compensate for sensor offset by adjusting either, or both, of the offset currents, I_{S-offset} 426 and I_{D-offset} 428.

Accordingly, the amplifier circuit 400 illustrated in FIG. 4 provides a user with the ability to control the current sources 402 and/or 404 to inject the offset currents I_{S-offset} 426 and I_{D-offset} 428 at desired current levels to create a voltage offset V_{offset} that offsets the sensor offset contribution to the input signal. The current sources 402 and 404 simplify the process of sensor offset compensation by providing the user with one or two parameters to adjust: I_{D-offset} 426 and/or I_{S-offset} 428. In one example, the user may set up a sensor to generate a ‘zero’ signal. Thus, in setting the input offset adjustment, the user may configure a sensor to generate a signal that is selected to represent a zero level. In the case of a TCD employed with a GC, the sensor may be configured to provide a balanced signal level at the sensor output leads. That is, the sensor may be subjected to a temperature at which all of the resistor filaments should be of equal value. The user may then adjust the current source(s) 402 and/or 404 to generate an I_{D-offset} 426 and/or I_{S-offset} 428 that applies a V_{offset} at the inverting inputs 422 and 424, which generates an output representative of a zero level of sample gas at the positive and negative outputs 440 and 442.

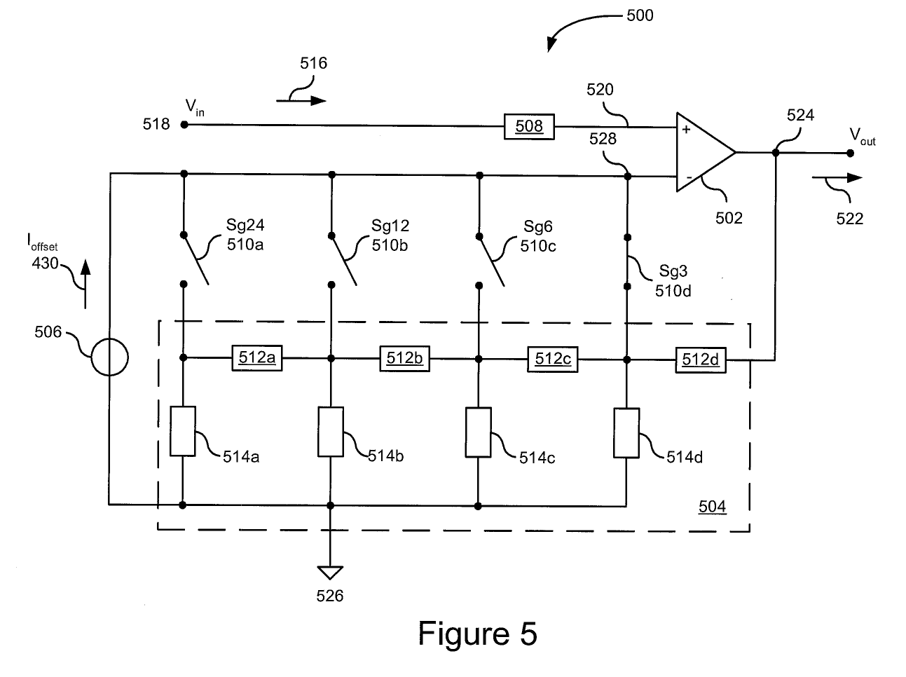

FIG. 5 is a schematic diagram of another example of a single-ended, programmable gain amplifier circuit 500 consistent with the present invention. The amplifier circuit 500 may include an amplifier 502, a feedback network 504, a current source 506, a compensating impedance 508, and a plurality of switches such as four switches 510a, 510b, 510c and 510d. The feedback network 504 may include an R2R impedance ladder network formed by series ladder impedances 512a, 512b, 512c and 512d, and parallel ladder impedances 514a, 514b, 514c and 514d, which are utilized as feedback for the amplifier 502. It is appreciated by those skilled in the art that while four switches 510a-d, four series ladder impedances 512a-d, and four parallel impedances 512a-d are shown, this number is an example and any number of these components may be utilized without departing from the scope of this invention. An input signal 516 may be received via signal input 518, which is in signal communication with a non-inverting input 520 of the amplifier 502 via the compensating impedance 508. The amplifier 502 outputs an amplified signal 522 at a signal output 524 of the amplifier 502 relative to signal ground 526.

The plurality of switches 510a, 510b, 510c, 510d may be a switch-bank that allows a user to select from a set of a plurality of gain settings. In this example, the switch Sg3 510d may be selected to set the gain of the amplifier circuit 500 to a gain value of 3. Similarly, the switch Sg6 510c may be selected to set the gain to a gain value of 6, the switch Sg12 510b may be selected to set the gain to a gain value of 12, and the switch Sg24 510a may be selected to set the gain to a gain value of 24. The gain settings are dependent on the configuration of the impedance elements in the R2R feedback network 504 for each switch setting. For example, the switch Sg3 510d is illustrated in a closed state, leaving the impedance element 512d as the lone feedback impedance element in signal communication with the negative input (i.e., an inverting input 528 of the amplifier 502) and the output 524 of the amplifier 502. By opening the switch Sg3 510d and closing the switch Sg6 510c, the configuration of the R2R feedback network 504 changes to provide an increased feedback impedance relative to the impedance between the negative input node 528 of the inverting input of the amplifier 502 and signal ground 526. The values of the impedances may be selected such that the gain is thereby effectively doubled (i.e., to a gain value of 6). Similarly, opening the switch Sg6 510c and closing the switch Sg12 510b raises the gain to a gain value of 12, and opening the switch Sg12 510b and closing the switch Sg24 510a raises the gain to a gain value of 24.

The current source 506 may be adjusted to control the input offset at the negative amplifier input (i.e., the inverting input 528) of the amplifier 502. In this example, the negative input node impedance of the feedback network 504 as seen at the inverting input 528 does not change when a different gain is selected. In this example, the impedance values may be selected as follows: the series ladder impedances 512a, 512b and 512c and the parallel ladder impedance 514a may each be set of an impedance value of R, where R is a resistance value; and the parallel ladder impedances 514b, 514c and 514d and the series ladder impedance 512d may each be set to an impedance value of 2R. Given the impedance values indicated in this example, the voltage offset V_{offset} at the inverting input 528 of the amplifier 502 may be determined according to:

$${V}_{offset} = \frac{2 R}{3} {I}_{offset} .$$

The user may set the voltage offset V_{offset} to compensate for a determined sensor offset by adjusting the offset current I_{offset} generated by the current source 506.

The amplifier circuit 500 illustrated in FIG. 5 provides a user with the ability to control the current source 506 to inject the offset current I_{offset} to create a voltage offset V_{offset} that offsets the sensor offset contribution to the input signal 516. The gain may also be programmed using the switches 510a, 510b, 510c, 510d in a manner that does not change the negative input node impedance of the feedback network 504 as seen at the inverting input 528 of the amplifier circuit 500, thereby eliminating the effect that changing the gain would otherwise have on the input offset adjustment.

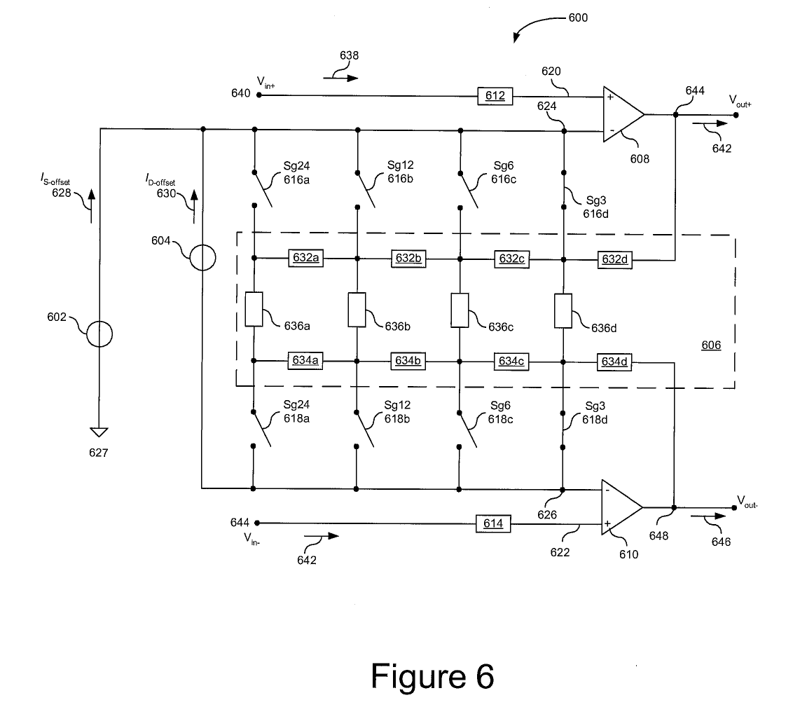

FIG. 6 is a schematic diagram of another example of a differential instrumentation, programmable gain amplifier circuit 600 consistent with the present invention. The amplifier circuit 600 may include first and second current sources 602 and 604, a feedback network 606, a first amplifier 608, a second amplifier 610, a first compensating impedance 612, a second compensating impedance 614, a first plurality of switches such as four switches 616a, 616b, 616c, 616d and a second plurality of switches such as four switches 618a, 618b, 618c, 618d. In this example, the first amplifier 608 and second amplifier 610 are differential amplifiers such as, for example, op-amps. The first compensating impedance 614 is in signal communication with a non-inverting input 620 of the first amplifier 608 and the second compensating impedance 614 is in signal communication with a non-inverting input 622 of the second amplifier 610. The first current source 602 is in signal communication with an inverting input 624 of the first amplifier 608. The second current source 604 is signal communication with both the inverting input 624 of the first amplifier 608 and an inverting input 626 of the second amplifier 610. The first current source 602 is also in signal communication with a signal ground 627. In operation, the first and second current sources 602 and 604 inject respective currents I_{S-offset} 628 and I_{D-offset} 630 directly into a first negative input node, which corresponds to the inverting input 624 of the first amplifier 608.

The feedback network 606 may include an R2R impedance ladder network formed by first (i.e., “upper”) series ladder impedances 632a, 632b, 632c and 632d; second (i.e. “lower”) series ladder impedances 634a, 634b, 634c and 634d; and parallel ladder impedances 636a, 636b, 636c and 636d, which are utilized as feedback for both amplifiers 608 and 610. It is appreciated by those skilled in the art that while four first switches 616a-d, four second switches 618a-d, four first series ladder impedances 632a-d, four second series ladder impedances 634a-d and four parallel impedances 636a-d are shown, this number is an example and any number of these components may be utilized without departing from the scope of this invention.

A first input signal 638 may be received via a signal input 640 (e.g., the positive signal input), which is in signal communication with the non-inverting input 620 of the first amplifier 608 via the first compensating impedance 612. The first amplifier 608 outputs a first amplified signal 642 at a signal output 644 of the first amplifier 608 relative to signal ground 627. Similarly, a second input signal 642 may be received via a signal input 644 (e.g., the negative signal input), which is in signal communication with the non-inverting input 622 of the second amplifier 610 via the second compensating impedance 614. The second amplifier 610 outputs a second amplified signal 646 at a signal output 648 of the second amplifier 610 relative to signal ground 627. As an example, a sensor may be put in signal communication with the differential positive and negative signal inputs 640 and 644.

The inverting amplifier input 624 of the first amplifier 608 is in signal communication with the feedback network 606 via the first switch-bank 616a-d at a first node that corresponds to the inverting input 624 to the first amplifier 608. The inverting amplifier input 626 of the second amplifier 610 is in signal communication with the feedback network 606 via the second switch-bank 618a-d at a second node that corresponds to the inverting input 626 to the second amplifier 610. The R2R impedance ladder network within the feedback network 606 is formed by the parallel ladder impedances 636a-d, upper series ladder impedances 632a-d, and lower series ladder impedances 634a-d.

The settings of the first and second switch-banks 616a-d and 618a-d switch the configuration of the impedances in the feedback network 606 to adjust the impedance values to obtain a desired gain. For example, the switch Sg3 616d in the first switch-bank 616a-d and the switch Sg3 618d in the second switch-bank 618a-d may be selected to set the gain of the amplifier circuit 600 to a gain value of 3. Similarly, the switches Sg6 616c and 618c in each switch-bank 616a-d and 618a-d may be selected to set the gain to gain value of 6, the switches Sg12 616b and 618b in each switch-bank 616a-d and 618a-d may be selected to set the gain to gain value of 12, and the switches Sg24 616a and 618a in each switch-bank 616a-d and 618a-d may be selected to set the gain to a gain value of 24. In these examples, the gains are dependent on the impedance of the R2R impedance ladder network, within the feedback network 606, corresponding to the switch or switches that are closed.

As an example of operation, the first current source 602 injects a current, I_{S-offset} 628, at the first node corresponding to the inverting input 624 of the first amplifier 608. The current, I_{S-offset} 628, generates a voltage offset at the inverting input 624 relative to signal ground 627. The second current source 604 injects a current, I_{D-offset} 630 into the R2R impedance ladder network to create a constant voltage drop across the R2R impedance ladder network between nodes corresponding to the inverting input 624 of first amplifier 608 and the inverting input 626 of the second amplifier 610. The first and second current sources 602 and 604 may be adjusted to generate a voltage offset, V_{offset}, to compensate for a sensor offset at the signal inputs 640 and 644. In this example, the impedance values may be selected as follows: upper series impedances 632a, 632b, and 632c and lower impedances 634a, 634b, and 634c have individual impedance values set to a resistance value of R; upper series impedance 632d and lower series impedance 634d have individual impedance values set to a resistance value of 2R; parallel impedances 636b, 636c, and 636d have individual impedance values set to a resistance value of 4R; and parallel impedance 636a has an impedance value set to a resistance value of 2R. Given the impedance values indicated in this example, the voltage offset V_{offset} may be determined by:

$${V}_{offset} = \frac{2 R}{3} {I}_{S \text{-} offset} + \frac{4 R}{3} {I}_{D \text{-} offset} .$$

The amplifier circuit 600 illustrated in FIG. 6 provides a user with the ability to control the current sources 602 and/or 604 to inject the offset current to create a voltage offset V_{offset} that offsets the sensor offset contribution to the input signal. The gain may also be programmed using the switches 616a, 616b, 616c, 616d and 618a, 618b, 618c, 618d in a manner that does not change the impedance at the differential input (i.e., the input impedances of the feedback network 606 at the inverting inputs 624 and 626 of first and second amplifiers 608 and 610, respectively) of the amplifier circuit 600, thereby eliminating the effect that changing the gain would otherwise have on the input offset adjustment.

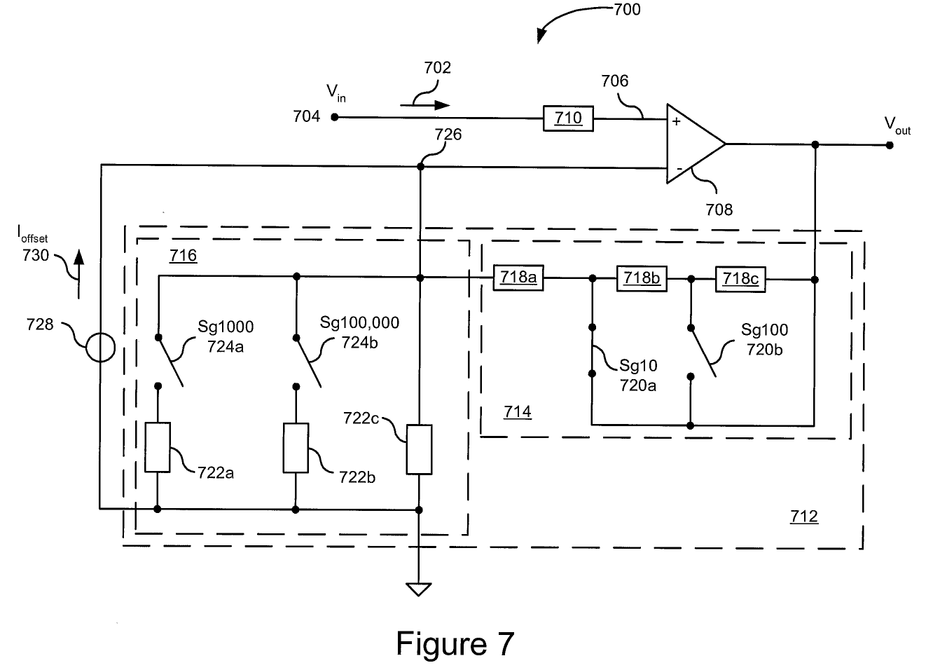

FIG. 7 is a schematic diagram of another example of a single-ended, programmable gain amplifier circuit 700 consistent with the present invention. The amplifier circuit 700 receives an input signal 702 at a signal input 704, which is in signal communication with a non-inverting input 706 of an amplifier 708 via a compensating impedance 710. The amplifier circuit 700 may include a feedback network 712 that has an R2R feedback network forming a voltage divider. The feedback network 712 may include a first feedback impedance network 714 and a second feedback impedance network 716. The first feedback impedance network 714 may include series-connected impedances 718a, 718b, and 718c. A first gain switch-bank that includes switches Sg10 720a and Sg100 720b is capable of adjusting the impedance of the first feedback impedance network 714 by switching in/out the series-connected impedances 718a, 718b, and 718c corresponding to the switch settings. The second feedback impedance network 716 includes parallel-connected impedances 722a, 722b, and 722c. A second gain switch-bank that includes switches Sg1000 724a and Sg100,000 724b is capable of adjusting the impedance of the second feedback impedance network 716 by switching in/out the parallel-connected impedances 722a, 722b, and 722c corresponding to the switch settings. In this example, switch Sg10 720a sets the gain of the single-ended programmable gain amplifier circuit 700 to a gain value of 10 when it is closed. Likewise, switch Sg100 720b sets the gain to a gain value of 100, switch Sg1000 724a sets the gain to a gain value of 1000, and switch Sg100,000 724b sets the gain to a gain value of 100,000. The gain at each switch setting is determined by the impedance at each branch (i.e., the first feedback impedance network 714 and the second feedback impedance network 716) of the voltage divider formed by the R2R feedback network of the feedback network 712.

In this example, the amplifier circuit 700 has the property that the impedance of the negative input node corresponding to an inverting input 726 of the amplifier element 708 is constant regardless of the gain selected. As an example, the impedance values of the impedances may be selected as follows: the impedance 718a has a resistance value of 9R, the impedance 718b has a resistance value of 81R, the impedance 718c has a resistance value of 810R, the impedance 722a has a resistance value of 100R, the impedance 722b has a resistance value of 10R, the impedance 722c has a resistance value of R, and the compensating impedance 710 has a resistance value of

$$\frac{9}{10} R .$$

Given these impedance values, the impedance at a node corresponding to the inverting input 726, of the amplifier 708, is

$$\frac{9}{10} R .$$

A current source 728 injects a constant offset current, I_{offset} 730 into node 726 to generate a constant offset voltage V_{offset}. Based on the impedance values of this example, the voltage offset V_{offset} may be obtained utilizing the following relationship:

$${V}_{offset} \frac{9}{10} {RI}_{offset} .$$

The amplifier circuit 700 illustrated in FIG. 7 provides a user with the ability to control the current source 728 to inject the offset current I_{offset} to create a voltage offset V_{offset} that offsets the sensor offset contribution to the input signal 702. The gain may also be programmed using the switches 720a, 720b and 724a, 724b in a manner that does not change the impedance at the input of the amplifier circuit 700, thereby eliminating the effect that changing the gain would otherwise have on the input offset adjustment.

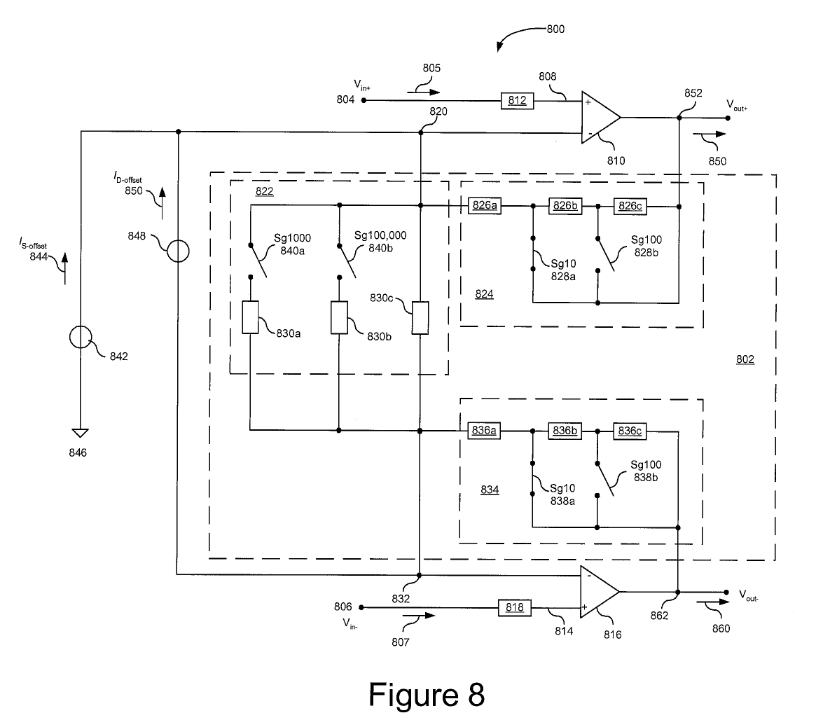

FIG. 8 is a schematic diagram of another example of a differential instrumentation programmable gain amplifier circuit 800 consistent with the present invention. The amplifier circuit 800 may include a feedback network 802 with switch-selectable impedance levels for both the gain impedance and the feedback impedance. A sensor may be in signal communication with the differential positive and negative inputs 804 and 806, at which first and second input signals 805 and 807 may be respectively received from the sensor. The positive signal input 804 is in signal communication with the non-inverting amplifier input 808 of a first amplifier 810 via a first compensating impedance 812. The negative signal input 806 is in signal communication with the non-inverting amplifier input 814 of a second amplifier 816 via a second compensating impedance 818. The first amplifier 810 outputs a first amplified signal 850 at a signal output 852 of the first amplifier 810. The second amplifier 816 outputs a second amplified signal 860 at a signal output 862 of the second amplifier 816.

An inverting amplifier input 820 of the first amplifier 810 is in signal communication with a gain impedance network 822 and to a first feedback impedance network 824. The first feedback impedance network 824 forms a branch of series-connected feedback impedances 826a, 826b and 826c communicating with a first switch-bank of switches 828a and 828b. The gain impedance network 822 forms a branch of parallel-connected gain impedances 830a, 830b and 830c between nodes 820 and 832 corresponding to the inverting inputs of the first and second amplifiers 810 and 816, respectively. Node 820 is in signal communication with the first feedback impedance network 824 and node 832 is in signal communication with a second feedback impedance network 834. The second feedback impedance network 834 may form a branch of series-connected feedback impedances 836a, 836b and 836c communicating with a second switch-bank of switches 838a and 838b. The impedances 830a-c of the gain impedance network 822 are in signal communication with a third switch bank of switches 840a and 840b. The gain may be set by selecting one of switches Sg10 828a and 838a, Sg100 828b and 838b, Sg1000 840a, or Sg100,000 840b. Switches Sg10 828a and 838a, and Sg100 828b and 838b, in the respective first and second switch-banks adjust the impedance of first and second feedback impedance networks 824 and 834 by switching in/out the series-connected impedances 826a-c and 836a-c in each branch to connect with the impedance 830c in the gain impedance network 822. Switches Sg1000 840a and Sg100,000 840b of the third switch-bank adjust the impedance of the gain impedance network 822 by switching in/out the parallel-connected impedances 830a-c to connect with the impedances of the first and second feedback impedance networks 824 and 834.

A first current source 842 injects a current I_{S-offset} 844 at node 820 at the inverting input of the first amplifier 810. The current I_{S-offset} 844 generates a voltage offset relative to signal ground 846 at the node 820. A second current source 848 injects a current I_{D-offSet} 850 into the gain impedance network 822 to create a constant voltage drop across the gain impedance network 822 between nodes 820 and 832. The first and/or second current sources 842 and 848 may be adjusted to generate a total voltage offset, V_{offset}, to compensate for a sensor offset at the signal inputs 804 and 806. As an example, the impedance values may be selected as follows: the impedances 826a and 836a are set to a resistance value of 9R, the impedances 826b and 836b are set to a resistance value of 81R, the impedances 826c and 836c are set to a resistance value of 810R, the impedance 830a is set to a resistance value of 200R, the impedance 830b is set to a resistance value of 20R, and the impedance 830c is set to a resistance value of 2R. Given these values, the voltage offset, V_{offset}, may be determined by:

$${V}_{offset} = \frac{9}{10} {RI}_{S \text{-} offset} + \frac{18}{10} {RI}_{D \text{-} offset} .$$

The amplifier circuit 800 illustrated in FIG. 8 provides a user with the ability to control the current sources 842 and/or 848 to inject the offset current to create a voltage offset V_{offset} that offsets the sensor offset contribution to the input signal. The gain may also be programmed using the switches 828a-b, 838a-b and 840a-b in a manner that does not change the impedance at the differential input (i.e., the input impedances of the feedback network 802 at the inverting inputs 820 and 832 of first and second amplifiers 810 and 816, respectively) of the amplifier circuit 800, thereby eliminating the effect that changing the gain would otherwise have on the input offset adjustment.

The examples of amplifier circuits described with reference to FIGS. 3-8 allow a user to set an input offset to compensate for a sensor offset. For the single-ended amplifier circuits such as the amplifier circuits 300, 500 and 700 shown in FIGS. 3, 5, and 7, a TCD in a bridge circuit may have one lead from the bridge circuit in signal communication with the single-ended input and the other lead grounded. In a GC application, the single-ended amplifier circuit may be configured and set to operate in the presence of the reference gas only. The input offset may be adjusted by adjusting the current source in the single-ended amplifier circuit until the output of the single-ended amplifier circuit is zero. Consequently, in the presence of a sample gas, the entire output gain range is available during operation.

Similarly, for the differential instrumentation amplifier circuits such as the amplifier circuits 400, 600 and 800 in FIGS. 4, 6 and 8, the leads of the bridge circuit of the TCD may be in signal communication with the differential inputs of the differential instrumentation amplifier circuits. The input offset may then be adjusted by adjusting the current(s) generated by the current source(s) in the differential instrumentation amplifier circuits with the TCD in the presence of a reference gas.

The programmable gain amplifier circuits such as the amplifier circuits 500, 600, 700 and 800 in FIGS. 5, 6, 7 and 8 enable the user to easily program the gain. The gain may be programmed by setting switches as described above or other suitable gain-adjusting devices or means. The switches may be implemented using any type of switch (e.g. a set of dipswitches, or electronic switches that may be controlled by software). Equal node impedances are provided for all gains, such that the required input offset adjustment is equal for all gains of the amplifier circuit.

One of more implementations may be configured such that the input offset adjustment is proportional to the bi-directional (positive or negative) offset input current. For a bridge circuit, a ratio-metric input offset adjustment can be realized by driving the offset adjustment current from a digital to analog converter with the bridge excitation as a reference.

It will be understood that various aspects or details of the invention may be changed without departing from the scope of the invention. For example, the impedance networks described by example above may be implemented using a variety of topographies that provide a constant impedance at the negative input of the amplifier elements regardless of the overall gain selected for the circuit. Moreover, specific impedances, gain settings, resistances, current and voltage offsets, and other values have been provided for purposes of illustration and example and thus are not limiting. Furthermore, the foregoing description is for the purpose of illustration only, and not for the purpose of limitation-the invention being defined by the claims.

What is claimed is:

1. An amplifier circuit, comprising:
an amplifier having a non-inverting input, an inverting input, and an amplifier output;
a feedback network in signal communication with the amplifier output and the inverting input; and
a current source in signal communication with the inverting input, the current source being adjustable to a plurality of selectable input offsets to generate a plurality of corresponding voltage offsets at the inverting input.

2. The amplifier circuit of claim 1, wherein the feedback network includes a first feedback impedance element in signal communication with the amplifier output and the inverting input, and a second feedback impedance element in signal communication with the inverting input.

3. The amplifier circuit of claim 2, wherein the first feedback impedance element has an impedance value dependent on the gain of the amplifier.

4. The amplifier circuit of claim 1, wherein the feedback network is adjustable to a plurality of gain settings of the amplifier circuit, and the feedback network is configured such that an impedance of the feedback network at the inverting input is equal for all gain settings, whereby the plurality of selectable input offsets and the plurality of corresponding voltage offsets are independent of the plurality of gain settings.

5. The amplifier circuit of claim 1, wherein:
the feedback network includes a plurality of impedance elements in signal communication with the inverting input, and a plurality of switches adjustable to a plurality of gain settings of the amplifier circuit; and
the feedback network is configured such that the impedance of the feedback network at the inverting input is equal for all gain settings, whereby the plurality of selectable input offsets and the plurality of corresponding voltage offsets are independent of the plurality of gain settings.

6. The amplifier circuit of claim 5, wherein the plurality of impedance elements includes a plurality of series-connected impedance elements in signal communication with the inverting input and the amplifier output, and a plurality of parallel-connected impedance elements in signal communication with the inverting input.

7. The amplifier circuit of claim 1, wherein:
the amplifier is a first amplifier, the non-inverting input is a first non-inverting input, the inverting input is a first inverting input, and the amplifier output is a first amplifier output;
the amplifier circuit further includes a second amplifier having a second non-inverting input, a second inverting input, and a second amplifier output; and
the feedback network is in signal communication with the second amplifier output and the second inverting input, in addition to the first amplifier output and the first inverting input.

8. The amplifier circuit of claim 7, wherein:
the current source includes a first current source in signal communication with the first inverting input, and a second current source in signal communication with the first inverting input and with the second inverting input; and
at least one of the first and second current sources is adjustable to the plurality of selectable input offsets to generate a plurality of corresponding voltage offsets at the first and second inverting inputs.

9. The amplifier circuit of claim 7, wherein the feedback network includes a first feedback impedance element in signal communication with the first amplifier output and the first inverting input, a second feedback impedance element in signal communication with the second amplifier output and the second inverting input, and a gain impedance element in signal communication with the first inverting input and the second inverting input.

10. The amplifier circuit of claim 9, wherein the first feedback impedance element and the second feedback impedance element each have an impedance value dependent on the gain of each of the first and second amplifiers.

11. The amplifier circuit of claim 7, wherein the feedback network is adjustable to a plurality of gain settings of the amplifier circuit, and the feedback network is configured such that the impedance between the first and second inverting inputs is equal for all gain settings, whereby the plurality of selectable input offsets and the plurality of corresponding voltage offsets are independent of the plurality of gain settings.

12. The amplifier circuit of claim 7, wherein:
the feedback network includes a plurality of impedance elements in signal communication with the first and second inverting inputs, and a plurality of switches adjustable to a plurality of gain settings of the amplifier circuit; and
the feedback network is configured such that the impedance between the first and second inverting inputs is equal for all gain settings, whereby the plurality of selectable input offsets and the plurality of corresponding voltage offsets are independent of the plurality of gain settings.

13. The amplifier circuit of claim 12, wherein the plurality of impedance elements includes:
a plurality of first series-connected impedance elements in signal communication with the first inverting input and the first amplifier output;
a plurality of second series-connected impedance elements in signal communication with the second inverting input and the second amplifier output; and
a plurality of parallel-connected impedance elements in signal communication with the first and second inverting inputs.

14. The amplifier circuit of any of claims 1, wherein at least one amplifier is in signal communication with a gas detector.

15. The amplifier circuit of any of claims 1, wherein at least one amplifier is in signal communication with a bridge output of a bridge circuit, and the bridge circuit includes at least two temperature-sensitive resistive elements, one of the resistive elements communicating with a first gas source and the other resistive element communicating with a second gas source.

16. The amplifier circuit of any of claims 1, wherein at least one amplifier is in signal communication with a gas detector, and the gas detector is in flow communication with a chromatographic column.

17. A method for adjusting an input offset at an input of an amplifier circuit, comprising:
amplifying an input signal in a differential amplifier to generate an output signal;
feeding back the output signal through a feedback network to an inverting input of the differential amplifier; and
driving an adjustable current into the inverting input, the adjustable current being adjustable to a plurality of selectable input offsets to generate a plurality of corresponding voltage offsets at the inverting input.

18. The method of claim 17, further including adjusting the feedback network to a selected one of a plurality of selectable gain settings of the amplifier circuit, wherein the impedance at the inverting input is equal for any gain setting selected and adjustment of the current is independent of the selected gain setting.

19. The method of claim 18, further including receiving an input signal at a non-inverting input of the differential amplifier from a gas detector.

20. The method of any of claims 19, wherein the input signal is indicative of a concentration of a gas flowed from a chromatographic column.
